(19) United States
(12) Patent Application Publication
(10) Pub. No.: US 2024/0126180 A1
(43) Pub. Date: Apr. 18, 2024

(54) SCALING FOR DIE-LAST ADVANCED IC PACKAGING

(71) Applicant: Applied Materials, Inc., Santa Clara, CA (US)

(72) Inventors: Jang Fung CHEN, Cupertino, CA (US); Thomas L. LAIDIG, Richmond, CA (US); Chung-Shin KANG, San Jose, CA (US); Chi-Ming TSAI, San Jose, CA (US); Wei-Ning SHEN, Santa Clara, CA (US)

(21) Appl. No.: 18/484,016

(22) Filed: Oct. 10, 2023

Related U.S. Application Data
(60) Provisional application No. 63/379,936, filed on Oct. 18, 2022.

(51) Int. Cl. G03F 7/00

(52) U.S. Cl. CPC G03F 7/70508

(57) ABSTRACT

Embodiments of the present disclosure relate to a system, a software application, and methods of digital lithography for semiconductor packaging. The method includes comparing positions of vias and via locations, generating position data based on the comparing the positions of vias and the via locations, providing the position data of the vias to a digital lithography device, updating a redistributed metal layer (RDL) mask pattern according to the position data such that RDL locations correspond to the positions of the vias, and projecting the RDL mask pattern with the digital lithography device.

### RELATED APPLICATIONS

This application claims benefit of and priority to U.S. Application No. 63/379,936, filed Oct. 18, 2022, and U.S. Application No. 63/380,223, filed Oct. 19, 2022, which are herein incorporated in their entirety by reference for all purposes.

### BACKGROUND

### Field

Embodiments of the present disclosure generally relate to lithography systems. More particularly, embodiments of the present disclosure relate to a system, a software application, and methods of digital lithography for semiconductor packaging.

### Description of the Related Art

Electronic packaging and assembly are typically used to link the small dimensions of an integrated circuit (IC) to an interconnecting substrate, for example, a printed circuit board (PCB) or an interposer. The PCB usually includes a number of passive components and ICs to build a microelectronic device, and the interposer is a connection board embedded into a packaged chip with a plurality of chiplet ICs on the interposer. As the semiconductor industry has experienced rapid growth due to ongoing improvements in the integration density of a variety of electronic components, for example, transistors, diodes, resistors, and capacitors. For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

For the foregoing reasons, there is a need for a system, a software application, and methods of lithography for semiconductor packaging.

### SUMMARY

In one embodiment, a method is provided. The method includes comparing positions of vias and via locations, generating position data based on the comparing the positions of vias and the via locations, providing the position data of the vias to a digital lithography device, updating a redistributed metal layer (RDL) mask pattern according to the position data such that RDL locations correspond to the positions of the vias, and projecting the RDL mask pattern with the digital lithography device.

In another embodiment, a method is provided. The method includes comparing positions of vias and via locations, generating position data based on the comparing the positions of vias and the via locations, providing the position data of the vias to a digital lithography device, generating a connection via mask pattern according to the position data, the connection via mask pattern includes connection vias having a first endpoint to contact the vias and a second endpoint to contact redistributed metal layer (RDLs) to be patterned at the via locations according to a RDL mask pattern, projecting the connection via mask pattern with the digital lithography device, the connection vias having the first endpoint to contacting the vias, and projecting the RDL mask pattern with the digital lithography device, the RDLs contacting the second endpoint of the connection vias.

In another embodiment, a non-transitory computer-readable medium is provided. The non-transitory computer-readable medium storing instructions that, when executed by a processor, cause a computer system to perform the steps of comparing positions of vias and via locations, generating position data based on the comparing the positions of vias and the via locations, providing the position data of the vias to a digital lithography device, generating a connection via mask pattern according to the position data, the connection via mask pattern includes connection vias having a first endpoint to contact the vias and a second endpoint to contact redistributed metal layer (RDLs) to be patterned at the via locations according to a RDL mask pattern, projecting the connection via mask pattern with the digital lithography device, the connection vias having the first endpoint to contacting the vias, and projecting the RDL mask pattern with the digital lithography device, the RDLs contacting the second endpoint of the connection vias.

In yet another embodiment, a packaging circuitry is provided. The packaging circuitry includes vias at via locations according to a via mask pattern of mask pattern data, connection vias having a first endpoint contacting the vias and a second endpoint to contact redistributed metal layer (RDLs) to be patterned at the via locations according to a RDL mask pattern of the mask pattern data, and RDLs contacting the second endpoint of the connection vias.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of a lithography system according to embodiments.

FIG. 2 is a perspective view of a digital lithography device according to embodiments.

FIG. 3 is a schematic view of a portion of a mask pattern according to embodiments.

FIG. 4 is a schematic view of an interface according to embodiments.

FIG. 5 is a schematic, top view of a packaging substrate after an embedding process according to embodiments.

FIG. 6 is a schematic, top view of a portion of the packaging substrate prior to a first operation of digital connection methods according to embodiments.

FIG. 7 is a flow diagram of a digital connection method according to embodiments.

FIG. 8 is a flow diagram of a digital connection method according to embodiments.

FIG. 9 is a schematic, top view of a portion of a packaging substrate after a fourth operation of a digital connection method according to embodiments.

FIG. 10A is a schematic, top view of a portion of a packaging substrate after a fourth operation of a digital connection method according to embodiments.

FIG. 10B is a schematic, top view of a portion of a packaging substrate after a fifth operation of the digital connection according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to lithography systems. More particularly, embodiments of the present disclosure relate to a system, a software application, and methods of digital lithography for semiconductor packaging.

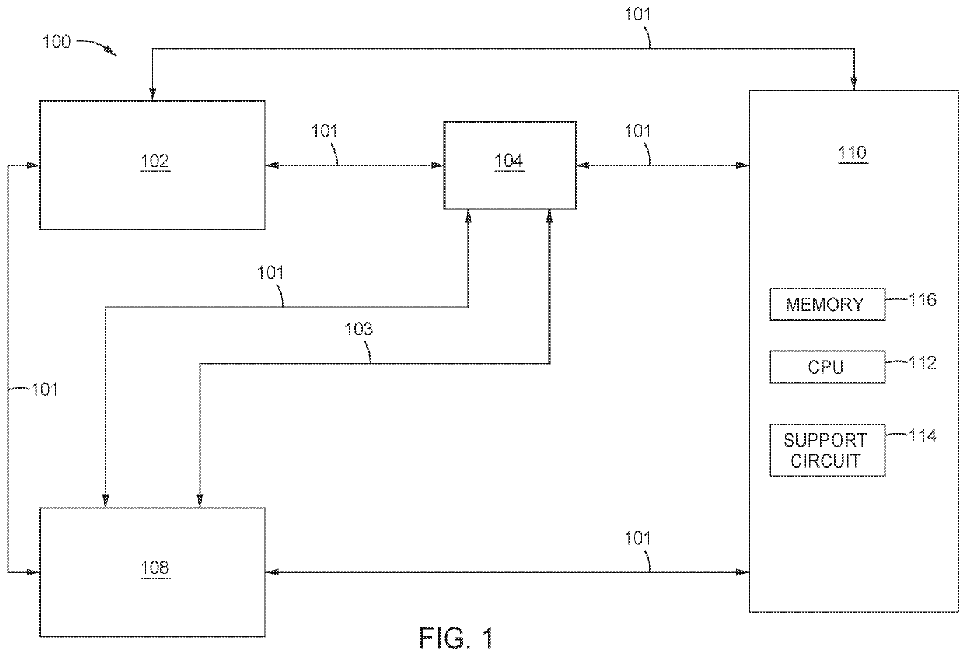

FIG. 1 is a schematic diagram of a lithography system 100. As shown, the lithography system 100 includes, but is not limited to, a virtual mask device 102, a metrology device 104, a digital lithography device 108, a controller 110, and a plurality of communication links 101. The lithography system 100 may further include a transfer system 103. The digital lithography device 108 and the metrology device 104 may be connected by the transfer system 103. The transfer system is operable to transfer a substrate between the digital lithography device 108 and the metrology device 104.

Each of the lithography system devices (the virtual mask device 102, the metrology device 104, the digital lithography device 108, and the controller 110) are operable to be connected to each other via the communication links 101. Alternatively or additionally, each of the lithography system devices can communicate indirectly by first communicating with the controller 110, followed by the controller 110 communicating with the lithography system device in question. The lithography system 100 can be located in the same area or production facility, or the each of the lithography system devices can be located in different areas.

Each of the plurality of lithography system devices are additionally indexed with digital connection methods 700, 800. Each of the virtual mask device 102, the metrology device 104, the digital lithography device 108, and controller 110 include an on-board processor and memory, where the memory is configured to store instructions corresponding to any portion of the method 500 described below. The communication links 101 may include at least one of wired connections, wireless connections, satellite connections, and the like. The communications links 101 facilitate sending and receiving files to store data, according to embodiments further described herein. Transfer of data along communications links 101 can include temporarily or permanently storing files or data in the cloud, before transferring or copying the files or data to a lithography environment device.

The controller 110 includes a central processing unit (CPU) 112, support circuits 114 and memory 116. The CPU 112 can be one of any form of computer processor that can be used in an industrial setting for controlling the lithography system devices. The memory 116 is coupled to the CPU 112. The memory 116 can be one or more of readily available memory, such as random access memory (RAM), read only memory (ROM), floppy disk, hard disk, or any other form of digital storage, local or remote. The support circuits 114 are coupled to the CPU 112 for supporting the processor in a conventional manner. These circuits include cache, power supplies, clock circuits, input/output circuitry, subsystems, and the like. The controller 110 can include the CPU 112 that is coupled to input/output (I/O) devices found in the support circuits 114 and the memory 116. The controller 110 is operable to facilitate and transfer a design file to the digital lithography device 108 via the communication links 101.

The memory 116 can include one or more software applications, such as a controlling software program. The memory 116 can also include stored media data that is used by the CPU 112 to perform the method 500 described herein. The CPU 112 can be a hardware unit or combination of hardware units capable of executing software applications and processing data. In some configurations, the CPU 112 includes a central processing unit (CPU), a digital signal processor (DSP), an application-specific integrated circuit (ASIC), and/or a combination of such units. The CPU 112 is generally configured to execute the one or more software applications and process the stored media data, which can be each included within the memory 116. The controller 110 controls the transfer of data and files to and from the various lithography system devices. The memory 116 is configured to store instructions corresponding to any operation of the digital connection methods 700, 800 according to embodiments described herein.

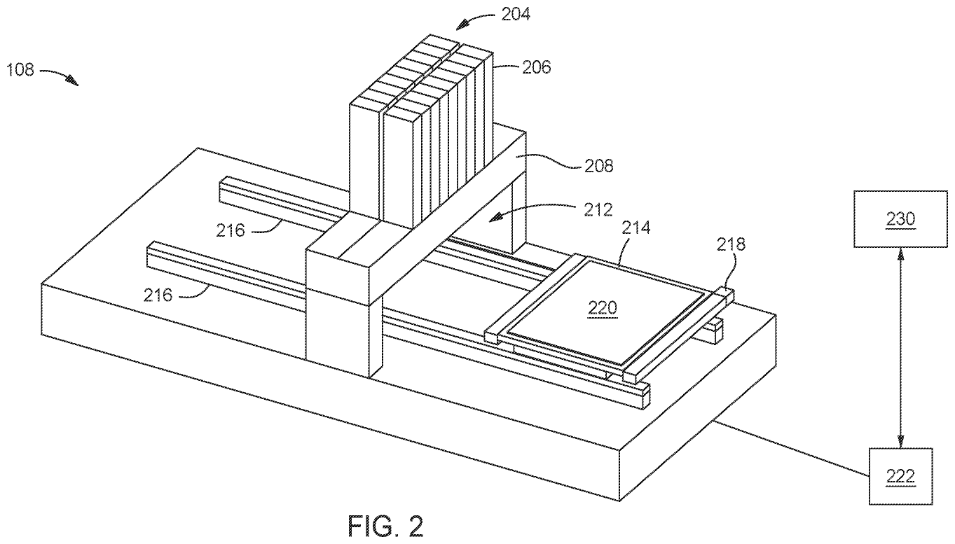

FIG. 2 is a perspective view of a digital lithography device 108, such as a digital lithography system, that may benefit from embodiments described herein. The digital lithography device 108 includes a stage 214 and a processing unit 204. The stage 214 is supported by a pair of tracks 216. A packaging substrate 220 is supported by the stage 214. The stage 214 is operable to move along the pair of tracks 216. An encoder 218 is coupled to the stage 214 in order to provide information of the location of the stage 214 to a lithography controller 222.

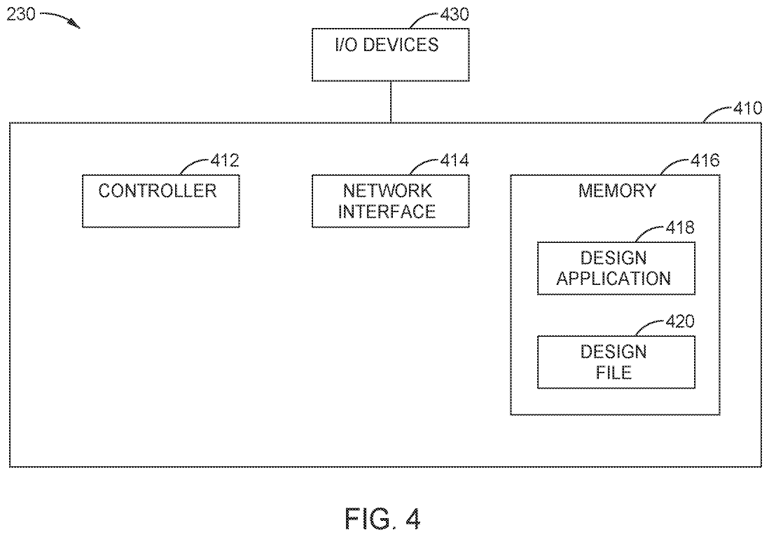

The lithography controller 222 is generally designed to facilitate the control and automation of the processing techniques described herein. The lithography controller 222 may be coupled to or in communication with the processing unit 204, the stage 214, and the encoder 218. The processing unit 204 and the encoder 218 may provide information to the lithography controller 222 regarding the substrate processing and the substrate aligning. For example, the processing unit 204 may provide information to the lithography controller 222 to alert the lithography controller 222 that substrate processing has been completed. The lithography controller 222 facilitates the control and automation of a digital lithography process based on a design file provided by the interface 230. The design file (or computer instructions), which may be referred to as an imaging design file, readable by the lithography controller 222, determines which tasks are to be performed on a substrate. The design file (e.g., the design file 420 of FIG. 4) includes a mask pattern data. The mask pattern data includes a mask pattern 300 and code to monitor and control the processing time and substrate position. The mask pattern 300 corresponds to a pattern to be written using the electromagnetic radiation.

The packaging substrate 220 comprises any suitable material, for example, glass. In other embodiments, which can be combined with other embodiments described herein, the packaging substrate 220 is made of other materials capable of being used as a part of the flat panel display. The packaging substrate 220 has a film layer to be patterned formed thereon, such as by pattern etching thereof, and a photoresist layer formed on the film layer to be patterned, which is sensitive to electromagnetic radiation, for example UV or deep UV “light”. A positive photoresist includes portions of the photoresist, when exposed to radiation, are respectively soluble to a photoresist developer applied to the photoresist after the pattern is written into the photoresist using the electromagnetic radiation. After exposure of the photoresist to the electromagnetic radiation, the resist is developed to leave a patterned photoresist on the underlying film layer. Then, using the patterned photoresist, the underlying thin film is pattern etched through the openings in the photoresist to form a portion of the packaging circuitry.

The processing unit 204 is supported by the support 208 such that the processing unit 204 straddles the pair of tracks 216. The support 208 provides an opening 212 for the pair of tracks 216 and the stage 214 to pass under the processing unit 204. The processing unit 204 is a pattern generator configured to receive the mask pattern data from the interface 230 and expose the photoresist in the maskless lithography process using one or more image projection systems 206 operable to project write beams of electromagnetic radiation to the packaging substrate 220. The pattern generated by the processing unit 204 is projected by the image projection systems 206 to expose the photoresist of the packaging substrate 220 to the mask pattern that is written into the photoresist. In one embodiment, which can be combined with other embodiments described herein, each image projection system 206 includes a spatial light modulator to modulate the incoming light to create the desired image. Each spatial light modulator includes a plurality of electrically addressable elements that may be controlled individually. Each electrically addressable element may be in an “ON” position or an “OFF” position based on the mask pattern data and corrections provided by positional correction models created through the method 500 described herein. When the light reaches the spatial light modulator, the electrically addressable elements that are in the “ON” position project a plurality of write beams to a projection lens (not shown). The projection lens then projects the write beams to the packaging substrate 220. The electrically addressable elements include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation.

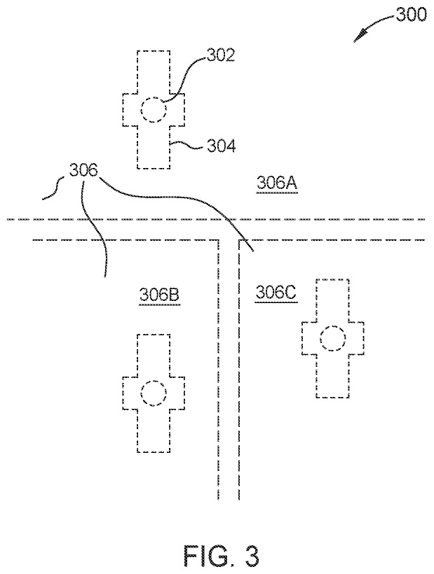

FIG. 3 is a schematic view of a portion of a mask pattern 300. The mask pattern 300 to be written into the photoresist using the processing unit 204. The mask pattern data includes a via mask pattern 301 and a redistributed metal layer (RDL) mask pattern 303. The via mask pattern 301 includes one or more via locations 302. The RDL mask pattern 303 includes one or more RDL locations 304. The via locations 302 and the RDL locations 304 correspond to interposers 306 (such as a first interposer 306A, a second interposer 306B, and a third interposer 306C) for dies to be attached in further packaging process. Each of the via locations 302 and RDL locations 304 include an x-coordinate and y-coordinate such that the metrology device 104 can perform recipe-based measurements at defined locations after the packaging substrate 220 is processed via the digital lithography device 108.

FIG. 4 is a schematic view of the interface 230. The interface 230 includes a computing device 410 and input/output (I/O) devices 430. The interface 230 may be utilized to at least one of optimize, verify, or update a design file (e.g., the design file 420). The interface 230 may be utilized to at least one of optimize, verify, or update the design file 420 per instructions and readable data of a Universal Metrology File (UMF) provide from one of the virtual mask device 102, the metrology device 104, and the assessment device 106, and the controller 110. The optimization, verification, and updating of the design file 420 is further described in operations of the digital connection methods 700, 800.

The computing device 410 may include a controller 412, a network interface 414, and memory 416. The controller 412 retrieves and executes programing data stored in the memory 416 and coordinates operations of other system components. Similarly, the controller 412 stores and retrieves application data residing in the memory 416. The controller 412 may be one or more central processing units (CPUs).

The memory 416 may store instructions and logic to be executed by the controller 412. Further, the memory 416 may be one or more of a random access memory (RAM) and a non-volatile memory (NVM). The NVM may be a hard disk, a network attached storage (NAS), and a removable storage device, among others. Further, the memory 416 may include a design application 418 and a design file 420.

The design application 418 at least one of optimizes, verifies, and updates the design data of the design file 420. The design application 418 may be controlled by the controller 412 to optimize, and/or update the design data of the design file 420.

The design file 420 may be stored within the memory 416 and is accessible by the controller 412 and the design application 418. The design file 420 includes the mask pattern data that is interpreted by the lithography controller 222 to pattern the photoresist disposed on the packaging substrate 220. The design file 420 may be provided in different formats. For example, the format of the design file 420 may be one of a GDS format, and an OASIS format, among others. The mask pattern data of the design file 420 includes the via mask pattern 301 and the RDL mask pattern 303. Other data included in the design file includes exposure dosage data, exposure focus data, and image projection system (IPS) to IPS calibration data. The exposure dosage data corresponds to the dosage of the write beams to be projected to the photoresist. The exposure focus data corresponds to the focus of the each of the image projection systems 206. The IPS to IPS calibration data corresponds to the stitching of the image projection systems 206 such the entirety of the mask pattern 300 is projected. The design file 420 may be in the form of a Bitmap or similar file.

The I/O devices 430 may include one or more of a keyboard, display device, mouse, audio device, and a touch screen, among others. The I/O devices 430 may be utilized to enter information into the virtual mask device 102 and/or output data from the virtual mask device 102. For example, a user may use a keyboard and a pointing device to generate and/or adjust elements of the design file 420. In another embodiment, which can be combined with other embodiments described herein, the I/O devices 430, via the network interface 414 in communication with the communication links 101, are coupled to the controller 110. The virtual mask device 102 being coupled to the controller provides for a computer-integrated manufacturing (CIM) procedure utilizing computers to control the entirety of the operations of the digital connection methods 700, 800 described herein.

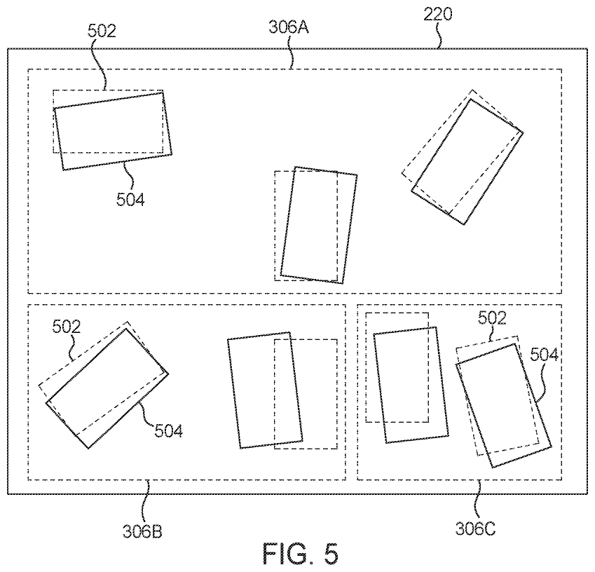

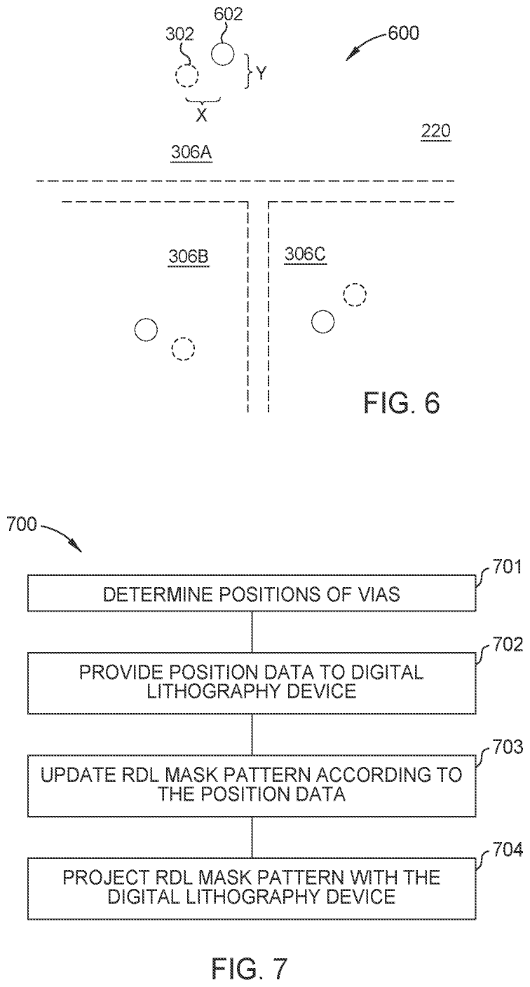

FIG. 5 is a schematic, top view of the packaging substrate 220 after an embedding process. FIG. 6 is a schematic, top view of a portion 600 of the packaging substrate 220 prior to a first operation of the digital connection methods 700, 800 described herein. The embedding process may be a process step of a die last packaging process. After the embedding process, devices 504 are disposed on the interposers 306. In the die last packaging process, dies are to be attached to respective interposers 306. The dies must align with the devices 504 and RDL circuits including vias 602 and RDLs 904. As shown in FIG. 5, the devices 504 may shift or rotate from desired device positions 502 as a result of the embedding process. The vias 602, as a result, may not be patterned on the via locations 302 of the via mask pattern 301 of the mask pattern date. For example, the vias 602 may have an x-shift and a y-shift from the x-coordinate and y-coordinate of via locations 302. In order for the dies to operate at their maximum capacity, the vias 602 must connect with the RDLs 904.

FIG. 7 is a flow diagram of the digital connection method 700. FIG. 9 is a schematic, top view of a portion 900 of the packaging substrate 220 after a fourth operation of the digital connection method. At operation 701, positions of the vias 602 are determined. The metrology device 104 determines at the positions and generates position data. The position data is generated by comparing the positions of vias 602 and the via locations 302. For example, x-shifts and y-shifts of the vias 602 from the x-coordinates and the y-coordinates of via locations 302 are determined. Position data is generated corresponding to the x-shifts and the y-shifts or the new x-coordinates and y-coordinates of the vias 602. At operation 702, the position data of the vias 602 is provided to the digital lithography device 108. The interface 230 of the digital lithography device 108 receives the position data from the metrology device 104 through the communication links 101 or from the controller 110 in communication with the metrology device 104.

At operation 703, the RDL mask pattern 303 of the mask pattern data is updated according to the position data. The interface 230 of the digital lithography device 108 may be utilized to at least one of optimize, verify, or update the design file 420 according to the position data. The mask pattern data is updated such that the RDL locations 304 of the RDL mask pattern 303 correspond to the position change of the vias 602 such that RDLs 904 align with the vias 602. At operation 704, the digital lithography device 108 projects the RDL mask pattern 303 updated according to the position data. The processing unit 204 of the digital lithography device 108 is a pattern generator configured to receive the mask pattern data with the updated RDL mask pattern 303 from the interface 230. The processing unit exposes the photoresist in the maskless lithography process using one or more image projection systems 206 operable to project write beams of electromagnetic radiation to the packaging substrate 220 according to the RDL mask pattern 303 updated according to the position data. After operation 704, the RDLs 904 align with the vias 602 for each of the interposers 306 (such as a first interposer 306A, a second interposer 306B, and a third interposer 306C).

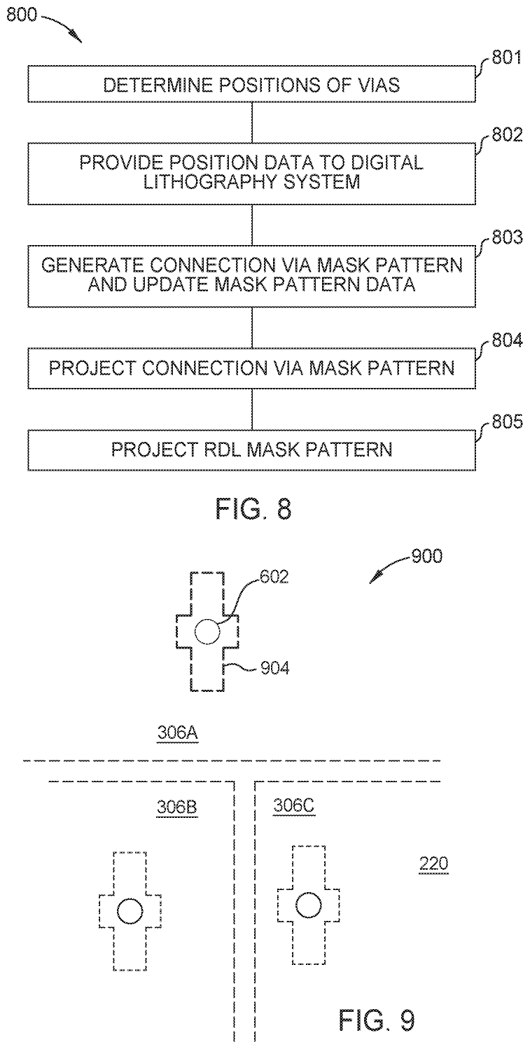

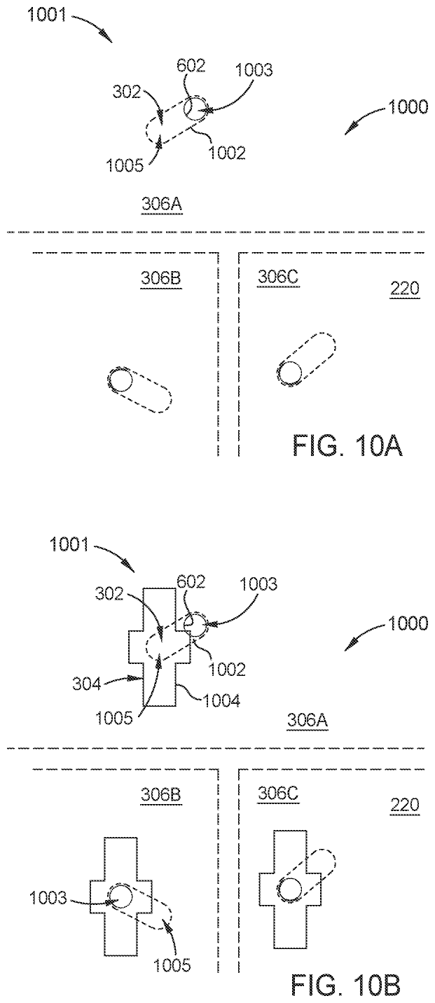

FIG. 8 is a flow diagram of the digital connection method 800. FIG. 10A is a schematic, top view of a portion 1000 of the packaging substrate 220 after a fourth operation of the digital connection method 800. FIG. 10B is a schematic, top view of the portion 1000 of the packaging substrate 220 after a fifth operation of the digital connection method 800. At operation 801, positions of the vias 602 are determined. The metrology device 104 determines at the positions and generates position data. For example, x-shifts and y-shifts of the vias 602 from the x-coordinates and the y-coordinates of via locations 302 are determined. Position data is generated corresponding to the x-shifts and the y-shifts or the new x-coordinates and y-coordinates of the vias 602. At operation 802, the position data of the vias 602 is provided to the digital lithography device 108. The interface 230 of the digital lithography device 108 receives the position data from the metrology device 104 through the communication links 101 or from the controller 110 in communication with the metrology device 104.

At operation 803, a connection via mask pattern 1001 is generated according to the position data and the mask pattern data is updated. The connection via mask pattern 1001 includes connection vias 1002 to connect the vias 602 to RDLs 1004 to be patterned to align with the via locations 302. The connection vias 1002 have a first endpoint 1003 to contact the vias 602 and a second endpoint 1005 to contact the RDLs 1004 at the via locations 302. The interface 230 of the digital lithography device 108 may be utilized to at least one of optimize, verify, or update the design file 420 with the connection via mask pattern according to the position data. The mask pattern data is updated such that the connection vias 1002 of the connection via mask pattern 1001 correspond to the position change of the vias 602 such that RDLs 1004 patterned at the RDL locations 304 of the RDL mask pattern 303 align with the second endpoint 1005 of the connection vias 1002 at the via locations 302.

At operation 804, the digital lithography device 108 projects the connection via mask pattern 1001. The processing unit 204 of the digital lithography device 108 is a pattern generator configured to receive the mask pattern data with the connection via mask pattern 1001 from the interface 230. The processing unit exposes the photoresist in the maskless lithography process using one or more image projection systems 206 operable to project write beams of electromagnetic radiation to the packaging substrate 220 according to the connection via mask pattern 1001 generated according to the position data.

At operation 805, the digital lithography device 108 projects the RDL mask pattern 303. The processing unit exposes the photoresist in the maskless lithography process using one or more image projection systems 206 operable to project write beams of electromagnetic radiation to the packaging substrate 220 according to the RDL mask pattern 303. The RDLs 1004 at the RDL locations 304 of the RDL mask pattern 303 contact the second endpoint 1005 of the connection vias 1002 at the via locations 302. The first endpoint 1003 of the connection vias 1002 contact the vias 602.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
comparing positions of vias and via locations;
generating position data based on the comparing the positions of vias and the via locations;
providing the position data of the vias to a digital lithography device;
updating a redistributed metal layer (RDL) mask pattern according to the position data such that RDL locations correspond to the positions of the vias; and
projecting the RDL mask pattern with the digital lithography device.

2. The method of claim 1, wherein a metrology device determines the positions of vias.

3. The method of claim 2, wherein an interface of the digital lithography device receives the position data.

4. The method of claim 1, wherein the position data includes x-shifts and y-shifts of the vias.

5. The method of claim 1, wherein an interface of the digital lithography device at least one of optimizes, verifies, or updates a design file.

6. The method of claim 1, wherein a processing unit of the digital lithography device is a pattern generator.

7. A method, comprising:
comparing positions of vias and via locations;
generating position data based on the comparing the positions of vias and the via locations;
providing the position data of the vias to a digital lithography device;
generating a connection via mask pattern according to the position data, the connection via mask pattern includes connection vias having a first endpoint to contact the vias and a second endpoint to contact redistributed metal layer (RDLs) to be patterned at the via locations according to a RDL mask pattern;
projecting the connection via mask pattern with the digital lithography device, the connection vias having the first endpoint to contacting the vias; and
projecting the RDL mask pattern with the digital lithography device, the RDLs contacting the second endpoint of the connection vias.

8. The method of claim 7, wherein a metrology device determines at the positions and generates the position data.

9. The method of claim 8, wherein an interface of the digital lithography device receives the position data from the metrology device.

10. The method of claim 7, wherein the position data includes x-shifts and y-shifts of the vias.

11. The method of claim 7, wherein an interface of the digital lithography device at least one of optimizes, verifies, or updates a design file.

12. The method of claim 7, wherein a processing unit of the digital lithography device is a pattern generator.

13. The method of claim 7, wherein the vias of disposed over interposers.

14. The method of claim 13, wherein dies are to be attached the interposers.

15. A non-transitory computer-readable medium storing instructions that, when executed by a processor, cause a computer system to perform the steps of:
comparing positions of vias and via locations;
generating position data based on the comparing the positions of vias and the via locations;
providing the position data of the vias to a digital lithography device;
generating a connection via mask pattern according to the position data, the connection via mask pattern includes connection vias having a first endpoint to contact the vias and a second endpoint to contact redistributed metal layer (RDLs) to be patterned at the via locations according to a RDL mask pattern;
projecting the connection via mask pattern with the digital lithography device, the connection vias having the first endpoint to contacting the vias; and
projecting the RDL mask pattern with the digital lithography device, the RDLs contacting the second endpoint of the connection vias.

16. The non-transitory computer-readable medium of claim 15, wherein a metrology device determines at the positions and generates the position data.

17. The non-transitory computer-readable medium of claim 16, wherein an interface of the digital lithography device receives the position data from the metrology device.

18. The non-transitory computer-readable medium of claim 15, wherein the position data includes x-shifts and y-shifts of the vias.

19. The non-transitory computer-readable medium of claim 15, wherein an interface of the digital lithography device at least one of optimizes, verifies, or updates a design file.

20. The non-transitory computer-readable medium of claim 15, wherein a processing unit of the digital lithography device is a pattern generator.

21. A packaging circuitry, comprising:
vias at via locations according to a via mask pattern of mask pattern data;
connection vias having a first endpoint contacting the vias and a second endpoint to contact redistributed metal layer (RDLs) to be patterned at the via locations according to a RDL mask pattern of the mask pattern data; and
RDLs contacting the second endpoint of the connection vias.

22. The packaging circuitry of claim 21, wherein the packaging circuitry includes interposers corresponding to the via locations.

23. The packaging circuitry of claim 21, wherein each of the via locations and RDL locations of the RDLs include an x-coordinate and y-coordinate.

24. The packaging circuitry of claim 21, wherein a connection via mask pattern includes the connection vias.

25. The packaging circuitry of claim 24, wherein the connection via mask pattern is generated based on position data of the vias.
